(19) United States
(12) Patent Application Publication
(10) Pub. No.: US 2014/0320232 A1
(43) Pub. Date: Oct. 30, 2014

(54) NETWORK SIGNAL TRANSMISSION MATCH DEVICE

(71) Applicant: KINNEXA, INC., Taipei City (TW)

(72) Inventor: KUAN-HSIUNG WEI, Taipei City (TW)

(73) Assignee: KINNEXA, INC., Taipei City (TW)

(21) Appl. No.: 13/945,922

(22) Filed: Jul. 19, 2013

(30) Foreign Application Priority Data
Apr. 26, 2013 (TW) 102207734

(51) Int. Cl. H03H 7/38

(52) U.S. Cl. CPC H03H 7/38
USPC 333/32

(57) ABSTRACT

A network signal transmission match device includes at least a substrate, at least a signal transmission component set, and at least a signal transformer connected in series with the signal transmission component set. The signal transmission component set is formed of at least a capacitor and an inductor connected in series and is mounted through SMT to the substrate. The signal transformer is electrically connected with the signal transmission component set. With the above structure, when the device is put into use, due to the correspondence and collaboration between the capacitor and the inductor, there is no impedance matching problem and the IEEE property is made better so as to greatly improve the operation characteristics thereof. As such, practical improvements of having excellent IEEE and EMI properties, being free of impedance matching problem, and providing efficient and stable manufacturability are achieved.

### TECHNICAL FIELD OF THE INVENTION

The present invention generally relates to a network signal transmission match device, and more particularly to a network signal transmission match device that shows excellent IEEE and EMI properties, has no impedance matching problem, and can be efficiently and stably manufactured.

### DESCRIPTION OF THE PRIOR ART

Due to diversity of manufacturing technology of different manufacturers, network connectors manufactured are often of difference in the final products thereof, but still in compliance with the standards and requirements of communication protocol issued by related associations and communities, such as IEEE (Institute of Electrical and Electronics Engineers) and EMI (Electro-Magnetic Interference).

To improve performance and obtain enhanced effect, all manufacturers are devoted themselves to the research and improvement of network connector and makes trials on various combinations of different electronic components, while keeping stick to the communication protocols, in an attempt to manufacture products having excellent performance.

A known network connector adopts an arrangement of connecting a plurality of signal transformers in cascade to provide the desired conditions of operation. However, when sold to users or manufactured, the signal transformers each show individual electrical characteristics (due to being affected by various factors, including density of wire wrapping, varying thickness of wires, or more detailedly the content of copper in the wires), so that a manually conducted fine adjustment is necessary for the manufacture of the network connector. This leads to a loss of manufacturing time and may further cause issues of matching and electromagnetic interference (due to wire stretching being varying in the manufacture that affect the EMI characteristics thereof). An apparent influence may thus be imposed on the speed and quality of transmission of information in networks.

Thus, it is desired, for the inventor and the manufacturers of the business, to provide a solution that helps overcome the above discussed problems and shortcomings.

### SUMMARY OF THE INVENTION

In view of the above problems, the present invention aims to a network signal transmission match device that shows excellent IEEE and EMI properties, has no impedance matching problem, and can be efficiently and stably manufactured.

The primary object of the present invention is to overcome the problem that the conventional signal transformers do not have consistent quality and specification by providing a substitute based on the circuit characteristics provided by serial connection of capacitor and inductor and, at the same time, to improve the effect of transmission and to eliminate instability of manual manufacture by applying surface mounting technology for manufacture of coupled capacitor and inductor. With such a technical solution, the problem of electromagnetic interference occurring in the conventional network connector can be overcome to thereby achieve the practical advantages of having excellent IEEE and EMI properties, being free of impedance matching problems, and having efficient and stable manufacturability.

To achieve the above object, the present invention provides a network signal transmission match device, which comprises at least a substrate, at least a signal transmission component set that is mounted to the substrate by means of surface mounting technology (SMT), and at least a signal transformer that is mounted to the substrate and is electrically connected to the signal transmission component set, wherein the signal transmission component set is formed of at least a capacitor and an inductor connected in series and the signal transformer comprises a plurality of magnetic coils that are connected in series with the inductor and the capacitor.

With such a structure, in manufacture, the capacitor and the inductor are mounted to the substrate by means of surface mounting technology (SMT) to form the signal transmission component set, which is then connected in series to the signal transformer, whereby in use, with the collaboration of the capacitor and the inductor, IEEE and EMI properties can be greatly improved and the manufacture can be simplified to also eliminate the impedance matching problems, so as to achieve the practical improvements of the present invention.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a block diagram showing the structure of a preferred embodiment of the present invention.

FIG. 2 is a schematic view showing the structure of a preferred embodiment of the present invention.

FIG. 3 is a schematic view showing an application of the preferred embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

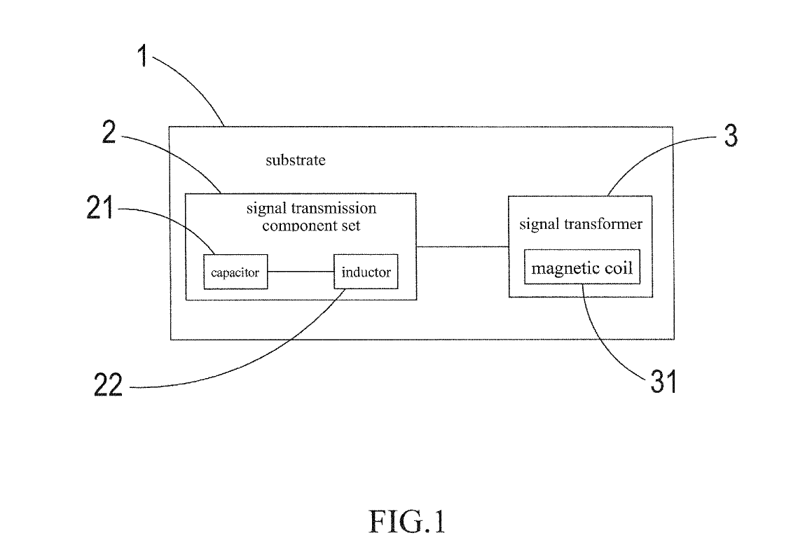

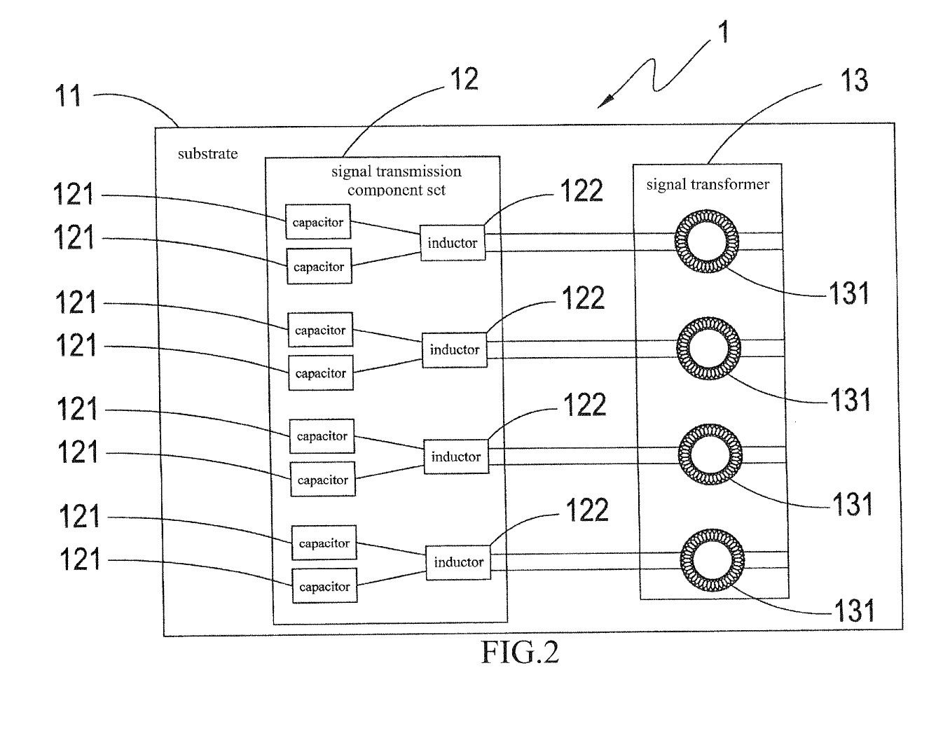

Referring to FIGS. 1 and 2, which are respectively a block diagram and a schematic view showing the structure of a preferred embodiment of the present invention, the drawings clearly show that the present invention comprises:

at least one substrate 1;

at least one signal transmission component set 2, wherein the signal transmission component set 2 is formed of at least one capacitor 21 and at least one inductor 22 that are connected in series and the signal transmission component set 2 is mounted, via surface mounting technology (SMT), to the substrate 1; and

at least one signal transformer 3 that is connected in series with the signal transmission component set 2, wherein the signal transformer 3 and the signal transmission component set 2 are electrically connected and mounted on the substrate 1 and the signal transformer 3 comprises a plurality of magnetic coils 31, which is respectively connected in series to the inductor 22 and the capacitor 21.

The substrate 1 is a printed circuit board (PCB) and the substrate further comprises a cover that covers the signal transformer 3.

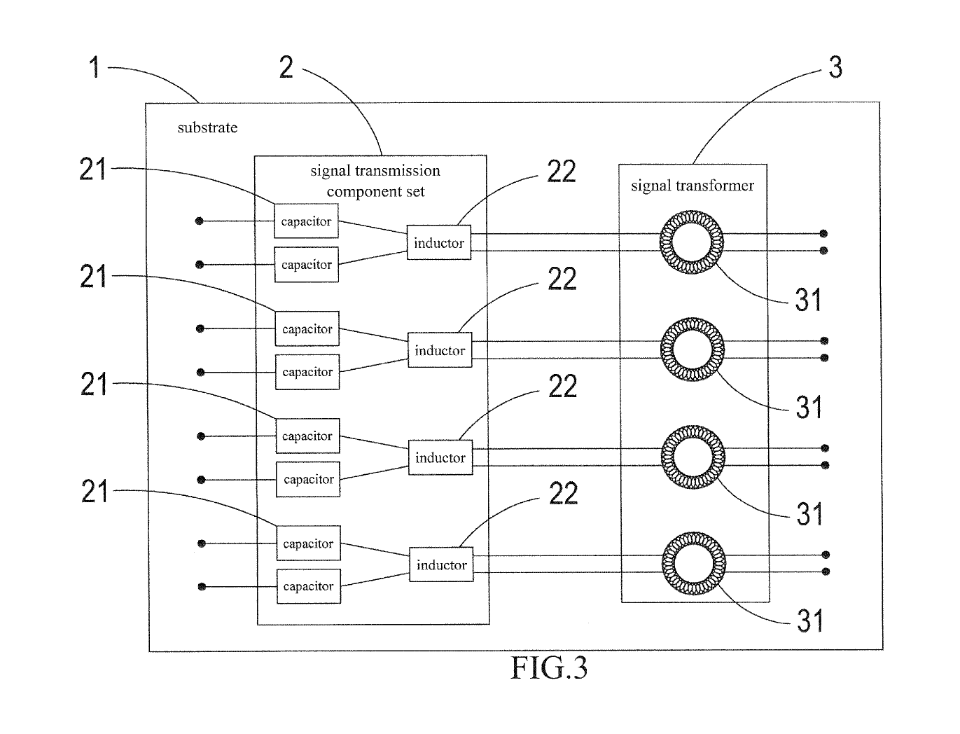

Also referring to FIGS. 1, 2, and 3, which are respectively a block diagram and a schematic view showing the structure of a preferred embodiment of the present invention and a schematic view showing an application of the preferred embodiment of the present invention, these drawings clearly show that in manufacturing the network signal transmission match device according to the present invention, a substrate 1 is first provided and signal transmission component sets 2 and signal transformers 3 that are of numbers determined according to the need of manufacture are further provided and mounted to the substrate 1, wherein the signal transmission component sets 2 are mounted to the substrate 1 by means of surface mounting technology (SMT), so that the manufacture can be carried out very efficiently thereby effectively improving the manufacturing efficiency and the quality of product. The magnetic coils 31 are respectively connected, in series, to the inductors 22 and the capacitors 21 to serve as a substitute for the conventionally used dual coil arrangements and also eliminate impedance match problems. Further, since the inductors 22 and the capacitors 21 are generally specification-complied standard products, which help significantly reduce instability of property and achieve the IEEE required characteristics and provide excellent EMI characteristics. Further, the substrate 1 is provided with a cover that covers the signal transformers 3 to provide protection to the components on the substrate 1 during the use thereof. With the above discussed advantages and features, the shortcomings of the prior art are substantially improved to achieve the advantages that the present invention has excellent IEEE and EMI properties, has no impedance matching problems, and can be efficiently and stably manufactured.

Thus, the technical features that the network signal transmission match device according to the present invention adopts to improve the prior art are as follows:

An arrangement of serial connection of capacitors 21 and inductors 22 is used to replace the coil based conventional way and, when used in combination with the surface mounting technology (SMT), can completely overcome various problems of the prior art to achieve the practical advantages of having excellent IEEE and EMI properties, having no impedance matching problems, and being efficiently and stably manufacturable.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A network signal transmission match device, comprising:
at least one substrate;
at least one signal transmission component set, wherein the signal transmission component set is formed of at least one capacitor and at least one inductor that are connected in series and the signal transmission component set is mounted, via surface mounting technology, to the substrate; and
at least one signal transformer that is connected in series with the signal transmission component set, wherein the signal transformer and the signal transmission component set are electrically connected and the signal transformer comprises a plurality of magnetic coils, which is respectively connected in series to the inductor and the capacitor, whereby the signal transformer makes use of the capacitor and the inductor of the signal transmission component set to achieve IEEE property and eliminate impedance matching problem.

2. The network signal transmission match device according to claim 1, wherein the substrate comprises a printed circuit board.

3. The network signal transmission match device according to claim 1, wherein the substrate comprises a cover that covers the signal transformer.
